(19) United States
(12) Patent Application Publication
(10) Pub. No.: US 2026/0318955 A1
(43) Pub. Date: Oct. 15, 2026

(54) METHOD OF MANUFACTURING MEMBRANE PROBE

(71) Applicant: WEN-CHIN CHENG, KAOHSIUNG CITY (TW)

(72) Inventor: WEN-CHIN CHENG, KAOHSIUNG CITY (TW)

(21) Appl. No.: 19/556,061

(22) Filed: Mar. 4, 2026

(30) Foreign Application Priority Data
Apr. 10, 2025 (TW) 114113591

(51) Int. Cl. G01R 3/00; G01R 1/067

(52) U.S. Cl. CPC G01R 3/00; G01R 1/06738

(57) ABSTRACT

A method of manufacturing a membrane probe is to fabricate it from metal block via precision machining. First fixing a metal block on a working substrate, thereafter, patterning a first insulating layer on the working substrate, then patterning at least one conductive trace and insulating layers over the metal block and the working substrate layer by layer by photolithography. Thus the conductive trace and the metal block are connected. Next removing the working substrate to form a membrane metal block sheet, then machining the metal block to form a desired probe. Thereby the present method produces a probe that has sufficiently robust strength and a plurality of contact bumps on its end. The membrane probe is designated to contact the sides of the solder bump. Therefore, problems related to contact resistance and flip-chip bonding are solved accordingly.

### FIELD OF THE INVENTION

The present invention relates to semiconductor wafer testing, especially to a method of manufacturing a membrane probe.

### DESCRIPTION OF RELATED ART

It is well known that there are two basic requirements in high-frequency measurement that need to be met during wafer testing and packaging processes. In order to reduce inductance losses, first, the length of a probe is reduced to a micro-sized scale, particularly a drastic reduction in the length of a probe for application at higher frequency up to the radio frequencies. Therefore, the membrane probe card dedicated for testing higher frequency phase is imperative. Second, a flip-chip packaging technology utilizing solder bumps is introduced in the packaging process. A Cu-pillar solder bump is preferred. Moreover, during wafer testing, both low electrical contact resistance (C-res) between probe card and device and reliable solder bump quality during contact engagement are essential.

In general, an I/O conductor on an electronic device used for bonding external circuits is called a connection bump. The connection bump is placed on the uppermost position of the device, and the main types include aluminum pad and solder bump. During electrical tests, the membrane probe tip must stay in contact with the solder bump to form an electronic circuit, and the device is tested by the test instrumentation. The probe tip is called the contact bump. Currently the membrane probe contact bump is a single contact bump with a flat end that contacts the top of the solder bump when the membrane probe card engages with the device under test.

A method of constructing a membrane probe used in the industry is primarily based on U.S. Pat. No. 7,533,462 B2. A depression having a desired shape of a resulting probe by dimpling tool is made on a metal substrate. An insulating layer is patterned on the surface of the metal substrate and located around the depression. By an electroplating process, different conductive metals are filled into the depression to obtain the desired probe. Next the conductive metals are lapped to provide a flat overall surface, and then a conductive trace and insulating layers are made layer by layer by photolithography. Lastly the metal substrate is removed by acid liquid to obtain the membrane probe.

The prior art is characterized by two features: the formation of a depression with a dimpling tool corresponding to the shape of the desired probe, and the fabrication of the desired probe by electroplating. Following the formation of the desired probe, the membrane wiring structure is formed. Owing to limitations of the electroplating, the probe tip is demonstrated as a short, single contact bump with a flat end having poor mechanical strength. The probe tip can be a pyramidal-shape bump or a conical-shape bump, and both provide lateral scrubbing movement to remove oxide buildup on flat aluminum pads without quality issues in a wafer test process. With respect to the solder bumps on the device, the contact bump end is brought into contact with the solder bump on the top when the membrane probe card engages with the device under test. As shown in FIG. 1, the structure of the connection bump on a device and the contact bump of a membrane probe are described. A device 200 is provided and the connection bump includes a solder bump 201 and a copper pillar (Cu-pillar) 202. A top area 203 of the solder bump 201 is dedicated in flip-chip process at the next stage. As shown, the solder bump 201 has a diameter of d1, and its centerline is denoted as CL1. A membrane probe sheet 100 comprises a probe 101 and a membrane wiring structure 10. The membrane wiring structure 10 consists of at least one conductive trace 103 and an insulating film 102. The probe 101 comprises a probe base 113 and a contact bump 110. The contact bump 110 has a flat end with a diameter of d2, a centerline of CL2, and a side angle of θ. The probe base 113 and the conductive trace are connected and fixed in the insulating film 102. The membrane probe sheet 100, a support mechanism, and a printed circuit board (PCB) are assembled to form the membrane probe card. The complete support mechanism and PCB are not shown in the figure, only the process is described.

During wafer testing, as shown in FIG. 1 and FIG. 2, a prober drives the wafer to move upward so that the device 200 is brought into contact with the contact bump 110 and then further moved upward with a probe overtravel OT followed. The following are possible situations.

1. When the contact bump diameter (d2) is larger than the solder bump diameter (d1), the contact bump is pressed against the top of a solder bump 201 over the area 203. A probe mark left on the solder bump after the device is removed from the contact bump is shown in FIG. 2A. The advantage is that the solder bump 201 meets the physical integrity requirements, which is beneficial for the flip-chip process. However, the probe 101 cannot penetrate the oxide buildup that forms on the bump surface, leading to unacceptably high contact resistance. Furthermore, oxides that accumulate on the contact bump end are difficult to remove efficiently. This not only reduces test yields below the product's expected value but also leads to frequent offline maintenance of the probe card.

2. When the contact bump diameter (d2) is considerably smaller than the solder bump diameter (d1) and the centerlines CL2 and CL1 are aligned, the probe contact bump is pressed into the top of the solder bump over the area 203, forming an indentation immediately after the device is removed from the contact bump, and a probe mark formed is shown in FIG. 2B. The advantage is that it achieves adequate electrical contact resistance and target test yield by puncturing the surface oxide. However, the device is rejected at outgoing QC because of deformation of the solder bump 201.

3. When the contact bump diameter (d2) is considerably smaller than the solder bump diameter (d1), there is a side angle θ (θ>0) and a misalignment (ϵ>0). The contact bump pushes a part of the solder bump 201 to move outward because of the curved surface of the solder bump, side angle θ>0, and flexible insulating membrane structure when the device 200 is moved upward with probe overtravel OT. As a result, the solder bump 201 is damaged severely, as shown in FIG. 2C. The contact bump breaks the oxide layer on the solder bump to achieve low contact resistance. However, the device is rejected at outgoing QC due to severely deformed solder bumps. In some cases, the yield can be recovered through an additional re-bumping process. This leads to higher cost and lower yield, which are both serious problems. The alignment error results from multiple factors, including the manufacturing precision of the contact bumps, precision of the device's solder bumps, and the alignment precision of the prober. It should be noted that the alignment error between the probe 101 and the corresponding solder bump 201 cannot be entirely eliminated.

Indeed, with a single-contact-bump probe, it is difficult to ensure both good electrical contact resistance and the solder bump quality during wafer testing. Poor contact resistance lowers test yield, while bump damage compromises the subsequent flip-chip bonding process. The current contact bump cannot solve the problems mentioned above. Thus product quality and production cost are impacted in the industry.

### SUMMARY OF THE INVENTION

Therefore, to eliminate the drawbacks of prior art methods using electroplating process, the present invention provides a method of manufacturing a membrane probe that has a diversity of probe structures with sufficient strength to contact the solder bump on the sides. This configuration secures adequate electrical contact resistance and solder bump quality during contact engagement, and increases the lifetime of the membrane probe.

In order to achieve the above objects, a method of manufacturing a membrane probe according to the present invention includes the following steps.

First, a metal block is fixed on a working substrate. Then insulating layers and a conductive trace are patterned over the metal block and the working substrate by photolithography layer by layer. Next, the working substrate is removed and a membrane metal block sheet forms. The metal block is then processed by precision machining to form the desired probe. The contact bump of a probe has a diverse structure that allows for contact with the sides of the solder bump. Therefore, this side-contact approach thereby solves the aforementioned problems associated with the top-contact method.

Preferably, the precision machining employed is ultra-short pulse laser machining.

Preferably, the membrane probe end is composed of a plurality of contact bumps.

Preferably, the contact bumps of the membrane probe are in contact with the sides of the corresponding solder bump without a lateral movement.

### BRIEF DESCRIPTION OF THE DRAWINGS

FIG. 1 is a schematic drawing showing a solder bump on a device and a single planar contact bump on a membrane probe end of a prior art;

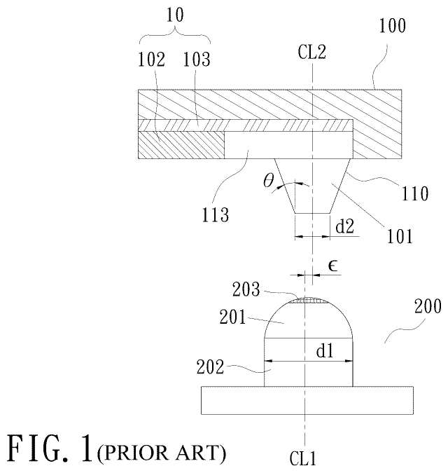

FIG. 2 is a series of schematic drawings (A), (B), and (C) showing probe marks after contact with a top of a solder bump with prior art;

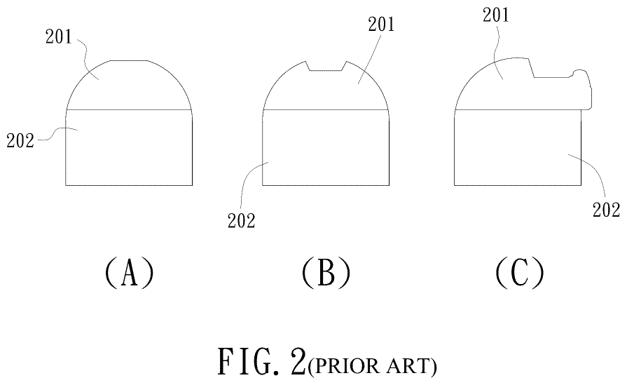

FIG. 3 is a perspective view of a working substrate of an embodiment according to the present invention;

FIG. 4 is a perspective view of a metal block of an embodiment according to the present invention;

FIG. 5 is a sectional view of a working substrate with a depression formed thereon of an embodiment according to the present invention;

FIG. 6 is a sectional view of a working substrate with a metal block fixed in a depression on the working substrate of an embodiment according to the present invention;

FIG. 7 is a sectional view of a working substrate patterned with an insulating layer of an embodiment according to the present invention;

FIG. 8 is a sectional view of an embodiment in which a membrane wiring structure is produced layer by layer of an embodiment according to the present invention;

FIG. 9 is a sectional view of a membrane metal block sheet of an embodiment according to the present invention;

FIG. 10 is a sectional view of a membrane probe provided with a multi-contact bump on an end of the membrane probe of an embodiment according to the present invention;

FIG. 11 is a sectional view showing a membrane probe provided with a single-contact bump on an end of the membrane probe of an embodiment according to the present invention;

FIG. 12 is a sectional view showing four contact bumps on an end of a probe and a corresponding device Cu-pillar solder bump of an embodiment according to the present invention;

FIG. 13 is a perspective view showing four contact bumps on an end of a probe of an embodiment according to the present invention;

FIG. 14 is a schematic drawing showing four contact bumps in contact with a solder bump and both centerlines aligned with each other of an embodiment according to the present invention;

FIG. 15 is a sectional view of the four contact bumps in FIG. 14 viewed from another direction of an embodiment according to the present invention;

FIG. 16 is a sectional view showing distribution of forces applied to a solder bump of an embodiment according to the present invention;

FIG. 17 is a top view showing four probe marks on a solder bump on a device of an embodiment according to the present invention;

FIG. 18 is a schematic drawing showing four contact bumps in contact with a solder bump but both centerlines misaligned with each other in an embodiment according to the present invention;

FIG. 19 is a perspective view showing four claw-like contact bumps on an end of a probe of another embodiment according to the present invention;

FIG. 20 is a top view showing four probe marks on a solder bump of an embodiment according to the present invention.

### DETAILED DESCRIPTION OF THE PREFERRED EMBODIMENT

In order to learn the technical content and functions of the present invention more clearly and completely, please refer to the following embodiments. The terms used in the present invention are open-ended terms. For example, “multi-contact bump on an end” includes terms such as multiple claws on a probe end and multiple bumps on the probe end, with innermost surfaces parallel to the probe centerline.

There is a plurality of probes on a membrane probe card. In the present invention, only manufacturing one probe is described in detail. Other probes are produced by the same method. As to the photolithography and the membrane wiring structure, they are not described in detail because they are not within the scope of the present invention.

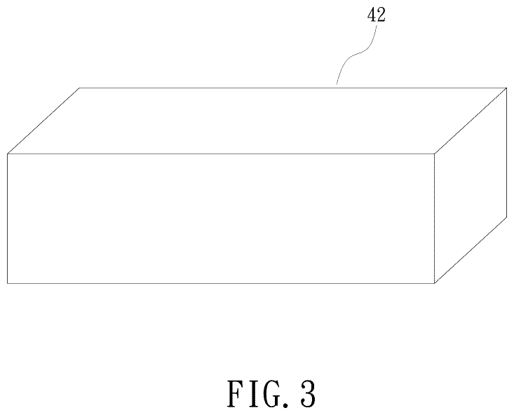

Refer to FIG. 3-FIG. 10, a method of manufacturing a membrane probe includes the following steps.

S1: disposing a working substrate 42 and a metal block 41;

S2: setting up a depression 421 on an upper surface of the working substrate 42. The metal block 41 has a first end 411 and a second end 412. The first end of the metal block 41 is mounted in the depression 421 so that the metal block 41 is positioned and fixed in the depression 421 and the second end of the metal block 41 is exposed outside the depression 421;

S3: constructing a membrane wiring structure 43 on the second end 412 of the metal block 41 and the working substrate 42 by photolithography. A first insulating layer 431 is patterned and supported on the working substrate, which is distributed around the second end 412 of the metal block 41;

S4: continuously patterning at least one conductive trace 432 on the second end surface 412 and the first insulating layer 431, then a second insulating layer 433 patterned over the surface by the photolithography to complete the membrane wiring structure 43 that connects the metal block thereby. The membrane wiring structure 43 is composed of the conductive trace 432, the first insulating layer 431, and the second insulating layer 433 in the embodiment;

S5: removing the working substrate 42 to form a membrane metal block sheet 410;

S6: performing precision machining on the metal block 41 to form a desired probe 44 and completing production of a membrane probe sheet 400.

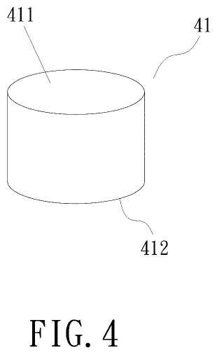

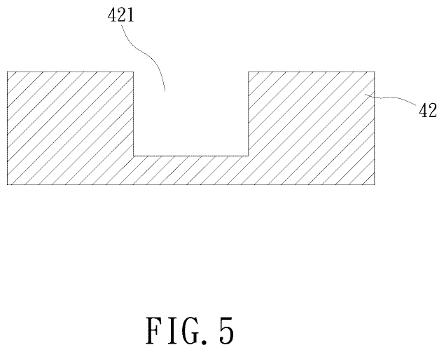

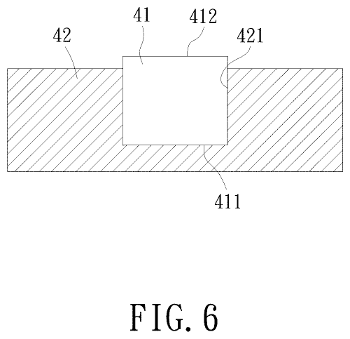

The following is a detailed description of the manufacturing processes. In the step S1, a working substrate 42 and a metal block 41 are provided. The working substrate 42 may be a metal substrate and the metal block 41 is made of metal materials with good electrical conductivity such as general metals, high-strength alloy, or hardened metals as shown in FIG. 3 and FIG. 4, respectively. The shape and size of the metal block 41 are not limited. In the step S2 of setting up a depression 421 on an upper surface of the working substrate 42, the depression 421 can be formed on the working substrate 42 in any way for positioning and fixing the metal block 41 therein, as shown in FIG. 5. The first end 411 of the metal block 41 is mounted into the depression 421 and the second end 412 is exposed outside, as shown in FIG. 6. Thereby the metal block 41 is fixed on the working substrate 42. The working substrate 42 is mainly used for fixing the metal block 41 and supporting the whole manufacturing processes of the membrane metal block sheet 410.

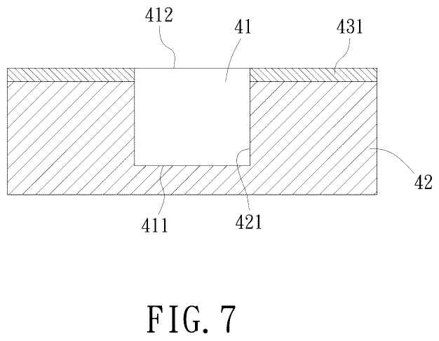

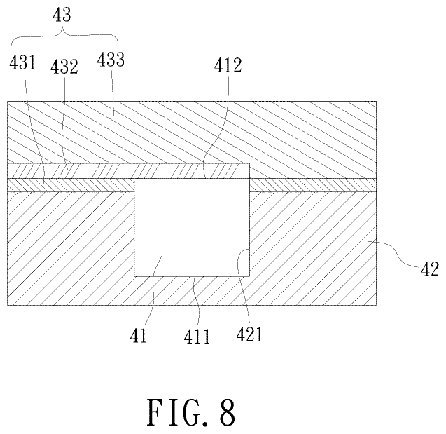

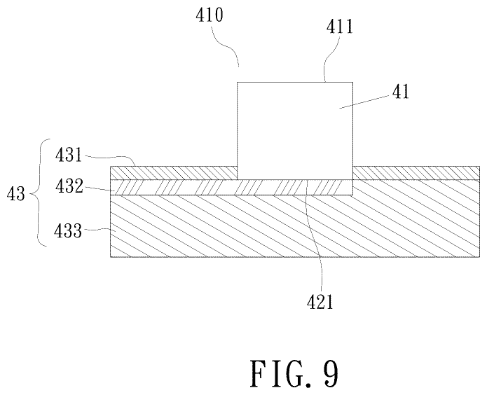

As shown in FIG. 7, patterning the first insulating layer 431 on the surface of the working substrate 42 and allowing the first insulating layer 431 to be distributed around the second end 412 of the metal block 41 in the step S3. In the step S4, continuously executing the photolithography for patterning a conductive trace 432 on the second end surface 412 and the first insulating layer 431, then the second insulating layer 433 patterned thereon, as shown in FIG. 8. Next, in the step S5, removing the working substrate 42 by suitable processes and allowing the first end 411 of the metal block 41 to be exposed for forming the membrane metal block sheet 410 which is comprised of the metal block and the membrane wiring structure 43, as shown in FIG. 9. At last, in the step S6, the metal block 41 is treated by precision machining to get the desired probe 44 whose length can be up to 50-150 micrometers for signal measurement at radiofrequency. Thereby the manufacturing process of the membrane probe 44 is completed.

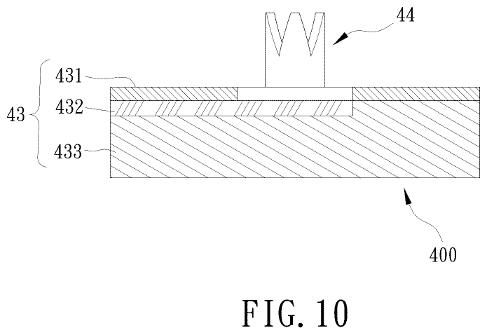

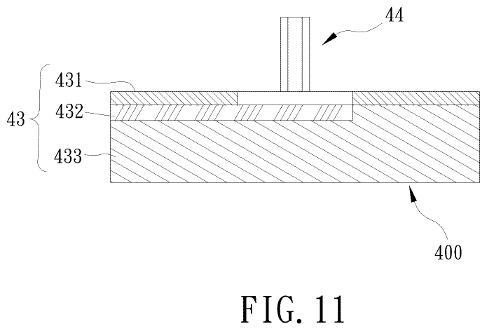

However, while executing the step S6, the metal block 41 can be processed to form the membrane probe 44 with a plurality of contact bumps on the probe end or a single contact bump on the probe base, as shown in FIG. 10 and FIG. 11, respectively. In contrast to the prior art that uses an electroplating process to form the desired probe at early stage, the present invention forms the probe from a metal block by precision machining at a later stage, only after the membrane wiring structure is completed. The precision machining can be ultra-short pulse laser machining or other suitable technologies.

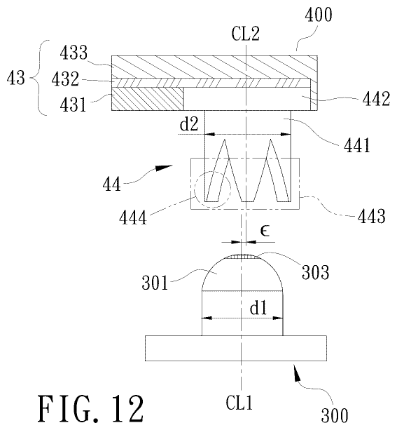

In a preferred embodiment in which the probe 44 is treated by precision machining, the metal block 41 is processed by three-axis ultra-short pulse laser to form the multi-contact-bump probe 44. As shown in FIG. 12, there are four contact bumps 444 on the probe end 443. How the contact bumps 444 are engaged into contact with the sides of the solder bump 301 is described in detail in the following embodiments.

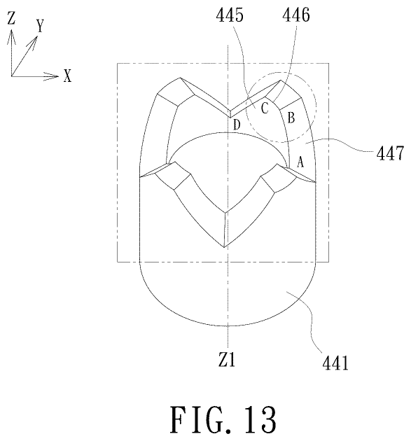

Refer to FIG. 12, a sectional view showing the four contact bumps 444 arranged on the probe end 443 and the corresponding solder bump on the device. The connection bump is a Cu-pillar solder bump. The membrane probe sheet 400 is composed of the probe 44 and a membrane wiring structure 43 which consists of at least one conductive trace 432, a first insulating layer 431, and a second insulating layer 433. The probe 44 includes a probe body 441 and a probe base 442. The probe end 443 is formed by the four contact bumps 444 arranged circularly, as shown in FIG. 13. Take the contact bump 444 on the upper right as an example. Each of the contact bumps 444 includes a vertical surface 445 disposed on an inner side which is in parallel to a centerline Z1 of the probe 44, a contact front edge 446 on an edge of the vertical surface 445, and a support body 447 located adjacent to and surrounding the vertical surface 445. For example, a vertical curved surface ABCDA is the vertical surface 445. A curved line BC is the contact front edge 446. Thereby the contact bumps on the probe end 443 are sufficient strong to contact the solder bump 301 on the device under test.

During wafer testing, a prober drives the wafer to move upward so that the connection bump (the solder bump 301) contacts the contact bumps 444 of the probe 44 and further moved upward with probe overtravel OT. The following are possible situations.

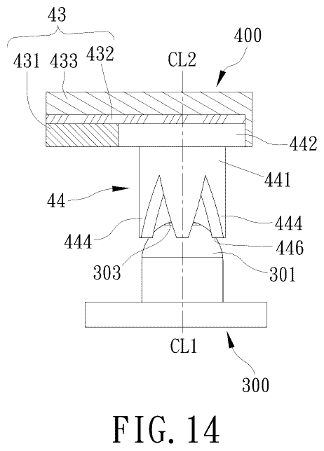

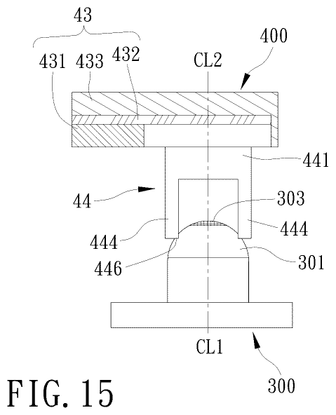

1. When both centerlines of the solder bump 301 and the probe 44 are aligned, the alignment error ϵ=0. The four contact front edges 446 first contact the sides of the solder bump 301 simultaneously, as shown in FIG. 14. The device 300 is lifted along with the probe overtravel OT so that the contact front edges 446 cut into the solder bump 301 and penetrate the oxide layer on the solder bump. Refer to FIG. 15, take a section in the z-x plane as an example. The two symmetrical contact front edges 446 penetrate the sides of the solder bump 301. The probe overtravel OT is absorbed by compression and deformation (unlabeled) of elastomer on the probe card. An action force and a reaction force are applied to the solder bump 301 and the contact bumps 444 simultaneously, respectively. The condition of the probe marks on the sides of the solder bump 301 is mainly determined by the probe overtravel OT, the contact bump structure, the number of the contact bumps, and the elastic coefficient of the elastomer. The optimal electrical contact resistance (C-res) and the probe marks 304 can be obtained by suitable design.

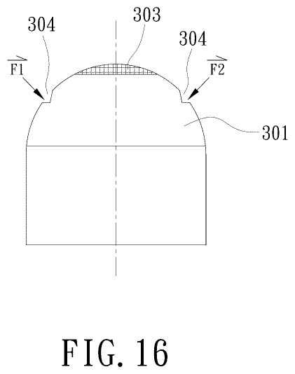

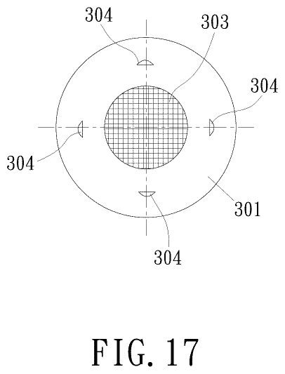

Refer to FIG. 16, a sectional view showing distribution of forces applied to a solder bump in the z-x plane is provided. The force F1 and the force F2 applied both by the probe 44 are distributed symmetrically and equal in magnitude. Thus a net lateral force on the x axis is zero so that no lateral movement applied to the solder bump is expected and solder bump quality is secured. Both forces are balanced by the structure strength of the solder bump 301. The vectors F1 and F2 both point from lateral sides toward the inside of the solder bump 301. Thereby the probe penetrates and removes the oxide layer on the contact area between the probe and the solder bump. This ensures a sufficient, effective, and stable electrical contact, resulting in low electrical contact resistance thereby. Simultaneously, a reaction force is also generated on an inner side of the contact bump during contact engagement. To counter it, the contact bump must be structurally robust to prevent collapse. Refer to FIG. 17, a top view showing the probe marks left on a solder bump upon the device removal from the contact bumps. The probe mark 304 on the side is an indentation formed by breaking through the oxide layer on the solder bump. Since the probe marks 304 are away from a flip-chip bonding area 303, the following flip-chip bonding will not be affected by the contact engagement.

To achieve stable electrical and mechanical contact, the contact bumps are arranged evenly around the probe end 443. This cancels out the net lateral force, ensuring stable contact. As long as the contact bumps on the probe end 443 are structurally robust, a suitable number of the contact bumps provides optimal electrical contact resistance (C-res). The present method ensures that the contact bumps have a sufficiently robust structure to avoid collapse problems.

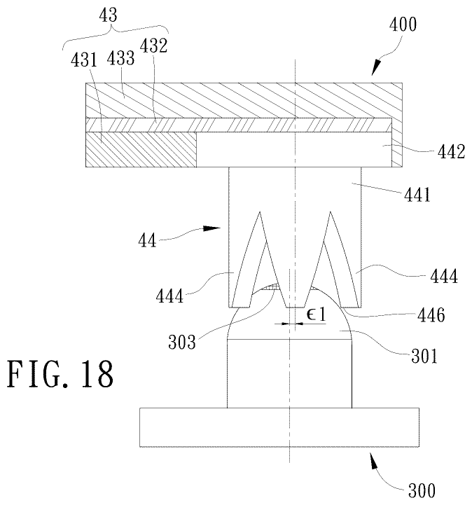

2. When both centerlines of the solder bump 301 and the probe 44 are misaligned, the alignment error is positive (ϵ>0). The four contact front edges 446 on probe 44 are unable to contact the sides of the solder bump 301 at the same time. The contact front edge 446 closest to centerline CL2 makes first contact. With further OT, it penetrates the side of the solder bump 301, thus fixing the contact position. Eventually all four contact front edges 446 are in contact with the solder bump 301 because of flexible membrane structure and curve surface of the solder bump, a distance between the two centerlines ϵ1 is almost equal to ϵ. That means there is no lateral movement, as shown in FIG. 18. The present method minimizes ϵ, leading to more uniform probe marks 304. Consequently, the physical integrity of the solder bump 301 and the flip-chip bonding area 303 remains unaffected.

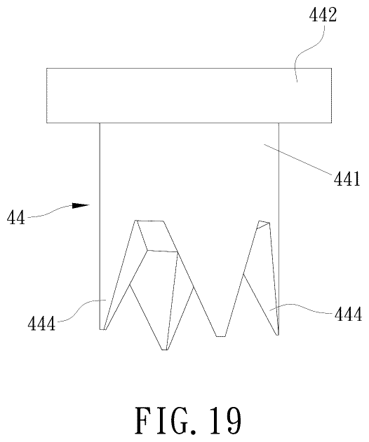

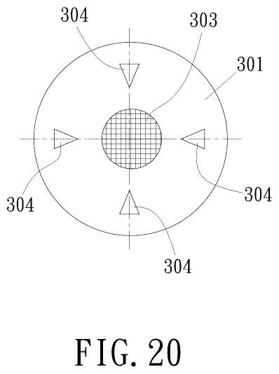

Refer to FIG. 19, a schematic drawing showing four claw-like contact bumps of another embodiment is provided. Also refer to FIG. 20, a top view showing probe marks left on a solder bump is provided. This embodiment has the same functions as the above one. The present invention provides a membrane probe manufacturing method that solves chronic problems inherent to the conventional method.

As demonstrated, the membrane probe constructed by the present invention ensures reliable sidewall contact with the solder bump and solves problems caused by the conventional method. This guarantees optimal electrical contact resistance and bump integrity, thereby securing robust flip-chip bonding during the packaging stage.

In summary, the present method employs metal block and precision machining process to construct the desired probe, offering the following advantages over the prior art that uses electroplating method.

1. The present manufacturing method is simpler, faster, cheaper, more reliable and more eco-friendly.

2. The present method can fabricate a plurality of contact bumps on the probe end to test the solder bump or a single contact bump to contact the aluminum pad, thereby demonstrating its broad applicability.

3. The shape and length of the probe are virtually unrestricted, being constrained only by the device's internal circuit frequency requirements and the probe's structural strength. In contrast, an electroplating-based method imposes strict limitations on these parameters due to manufacturing constraints such as non-uniform current density and ion concentration in the plating bath. Furthermore, the probe produced by high-strength metal block is more rigid than one constructed by the electroplating process, resulting in a longer probe lifetime.

4. The higher (x, y, z) positional precision of the probe is achieved through precision machining with accuracy controller, which processes metal blocks to form desired probes one by one in accordance with the pattern of connection bumps on the devices. This step corrects for location deviations of the depression, thereby achieving the overall accuracy of the probe card. In prior art, the probe position is fixed irreparably by the depression location prior to electroplating, which compromises probe card quality and reliability. In contrast, the present method delivers substantially improved precision for every membrane probe.

5. The probe is made of a high-strength metal or alloy. Thus, a plurality of contact bumps on the probe end is provided to contact the sides of the solder bump without risk of collapse.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

What is claimed is:

1. A method of manufacturing a membrane probe comprising the steps of:
S1: disposing a working substrate and a metal block;
S2: setting up a depression on an upper surface of the working substrate; the metal block having a first end and a second end; the first end of the metal block being mounted in the depression so that the metal block is positioned and fixed in the depression and the second end of the metal block is exposed outside the depression;
S3: producing a membrane wiring structure on the second end of the metal block by photolithography; first patterning a first insulating layer which is distributed around the second end of the metal block;
S4: continuously producing at least one conductive trace and a second insulating layer on the second end of the metal block and the first insulating layer by the photolithography to complete production of the membrane wiring structure; the membrane wiring structure having the conductive trace and insulating layers;
S5: removing the working substrate to form a membrane metal block sheet; and
S6: performing precision machining on the metal block to form a desired probe and completing production of the membrane probe.

2. The method as claimed in claim 1, wherein in the step S6, the precision machining employed is ultra-short pulse laser machining to process the metal block.

3. The method as claimed in claim 2, wherein the membrane probe end is composed of a plurality of contact bumps.

4. The method as claimed in claim 3, wherein the contact bumps are in contact with the sides of the corresponding solder bump.
